(19) United States
(12) Patent Application Publication
(10) Pub. No.: US 2025/0010605 A1
(43) Pub. Date: Jan. 9, 2025

(54) LAMINATION DEVICE AND DRIVING METHOD THEREOF

(71) Applicant: Samsung Display Co., LTD., Yongin-si (KR)

(72) Inventors: Tae Young PARK, Yongin-si (KR); Suk Ju KANG, Yongin-si (KR); Sang Cheol KIM, Yongin-si (KR); Jun Hee LEE, Yongin-si (KR); Min Seok KANG, Yongin-si (KR)

(73) Assignee: Samsung Display Co., LTD., Yongin-si (KR)

(21) Appl. No.: 18/625,732

(22) Filed: Apr. 3, 2024

(30) Foreign Application Priority Data
Jul. 7, 2023 (KR) 10-2023-0088675

(51) Int. Cl. B32B 38/18; H02N 13/00

(52) U.S. Cl. CPC B32B 38/1833; H02N 13/00; B32B 2038/1891

(57) ABSTRACT

A lamination device includes an upper chamber accommodating a window, a lower chamber accommodating at least one display panel, at least one shaft penetrating the lower chamber, at least one alignment part aligning the at least one display panel and the window, and at least one sub-chamber disposed between the lower chamber and the at least one alignment part. At least one bellows surrounding a portion of the at least one shaft may be disposed in the at least one sub-chamber.

### CROSS-REFERENCE TO RELATED APPLICATION(S)

This application claims priority to and benefits of Korean Patent Application No. 10-2023-0088675 filed on Jul. 7, 2023 under 35 U.S.C. § 119, in the Korean Intellectual Property Office (KIPO), the entire contents of which are incorporated herein by reference.

### BACKGROUND

### 1. Technical Field

The disclosure relates to a lamination device and driving method of the lamination device.

### 2. Description of the Related Art

With the development of information technologies, the importance of a display device which is a connection medium between a user and information increases. Accordingly, display devices such as a liquid crystal display device and an organic light emitting display device are increasingly used.

A display device may include a window and a display panel. The window may be provided to protect the display panel, and the window and the display panel may be attached to each other. A lamination device may be used to laminate the window and the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a lamination device and a driving method of the lamination device, which can allow a center of an alignment unit of the lamination device to readily correspond to centers of various types of display panels.

Embodiments also provide a lamination device and a driving method of the lamination device, which can prevent damage of a bellows in a process of allowing a center of an alignment unit and a center of a display panel to correspond to each other.

The technical objectives to be achieved by the disclosure are not limited to those described herein, and other technical objectives that are not mentioned herein would be clearly understood by a person skilled in the art from the description of the disclosure.

In accordance with an aspect of the disclosure, a lamination device may include an upper chamber accommodating a window; a lower chamber accommodating at least one display panel; at least one shaft penetrating the lower chamber; at least one alignment part aligning the at least one display panel and the window; and at least one sub-chamber disposed between the lower chamber and the at least one alignment part, wherein at least one bellows surrounding a portion of the at least one shaft is disposed in the at least one sub-chamber.

A first base plate and a first electrostatic chuck may be disposed in the upper chamber. The first electrostatic chuck may be disposed on the first base plate and fix the window.

At least one second base plate and at least one second electrostatic chuck may be disposed in the lower chamber. The at least one second base plate may be connected to the at least one shaft. The at least one second electrostatic chuck may be disposed on the at least one second base plate and fix the at least one display panel.

The lower chamber may include at least one opening hole corresponding to the at least one display panel. The at least one shaft may be disposed in the at least one opening hole.

The at least one sub-chamber may include a sub-plate including a fixing hole fixing the at least one shaft; a cylinder allowing the at least one sub-chamber to move upwards/downwards; a linear motion guide (or LM guide) guiding an up/down motion of the at least one sub-chamber; and a floating joint compensating for parallelism between an axial center of the cylinder and the up/down motion of the LM guide.

The upper chamber and the lower chamber may be joined together to form an internal space. The at least one bellows may maintain the internal space to be in a vacuum state.

The at least one bellows may be in contact with the sub-plate.

The lamination device may further include at least one single-axis robot disposed on the bottom of the at least one alignment part, the at least one single-axis robot moving the at least one alignment part such that a center of the at least one alignment part and a center of the at least one display panel correspond to each other.

The at least one sub-chamber may move downwards before the at least one single-axis robot moves the at least one alignment part.

The at least one sub-chamber may move upwards after the at least one single-axis robot moves the at least one alignment part.

A number of the at least one display panel may be in a range of 1 to 3.

In accordance with an aspect of the disclosure, a method of driving a lamination device may include lowering at least one sub-chamber disposed between a lower chamber accommodating at least one display panel and at least one alignment part; allowing a center of the at least one alignment part and a center of the at least one display panel to correspond to each other by moving the at least one alignment part; and raising the at least one sub-chamber, wherein at least one bellows surrounding a portion of at least one shaft is disposed in the at least one sub-chamber.

The at least one sub-chamber may include a sub-plate including a fixing hole fixing the at least one shaft; a cylinder allowing the at least one sub-chamber to move upwards/downwards; a linear motion guide (or LM guide) guiding an up/down motion of the at least one sub-chamber; and a floating joint compensating for parallelism between an axial center of the cylinder and the up/down motion of the LM guide.

The at least one bellows may be in contact with the sub-plate.

The method may further include joining together an upper chamber accommodating a window and the lower chamber; maintaining an internal space formed by joining together the upper chamber and the lower chamber to be in a vacuum state; and adhering the window and the at least one display panel to each other.

A number of the at least one display panel may be in a range of 1 to 3.

A first base plate and a first electrostatic chuck may be disposed in the upper chamber, and the first electrostatic chuck may be disposed on the first base plate and fixes the window.

At least one second base plate and at least one second electrostatic chuck may be disposed in the lower chamber, the at least one second base plate may be connected to the at least one shaft, and the at least one second electrostatic chuck may be disposed on the at least one second base plate and fixes the at least one display panel.

The method may further include moving the at least one sub-chamber downwards before moving the at least one alignment part by the at least one single-axis robot.

The method may further include moving the at least one sub-chamber upwards after moving the at least one alignment part by the at least one single-axis robot.

### BRIEF DESCRIPTION OF THE DRAWINGS

The above and other features of the disclosure will become more apparent by describing in further detail embodiments thereof with reference to the accompanying drawings, in which:

FIGS. 1 to 6 are schematic views illustrating various types of display devices.

FIGS. 7 and 8 are schematic views illustrating a lamination device in accordance with an embodiment of the disclosure.

FIG. 9 is a schematic view illustrating a lamination device in accordance with an embodiment of the disclosure.

FIG. 10 is a schematic view illustrating a sub-chamber in accordance with an embodiment of the disclosure.

FIGS. 11 to 13 are schematic views illustrating a driving method of a lamination device in accordance with an embodiment of the disclosure.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be more thorough and complete, and will convey the scope of the disclosure to those skilled in the art.

In describing the drawings, like reference numerals have been used for like elements. In the accompanying drawings, the dimensions of the structures are enlarged more than the actual size in order to clearly explain the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element.

The terminology used herein is for the purpose of describing embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” The terms “and” and “or” mean “and/or.” As used herein, the term “and/or” includes any and all combinations of one or more of the associated listed items.

It will be further understood that the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would be oriented “above” the other elements. The terms “below” or “beneath” can, therefore, encompass both an orientation of above and below.

Unless otherwise defined or implied herein, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the disclosure are described in detail with reference to the accompanying drawings.

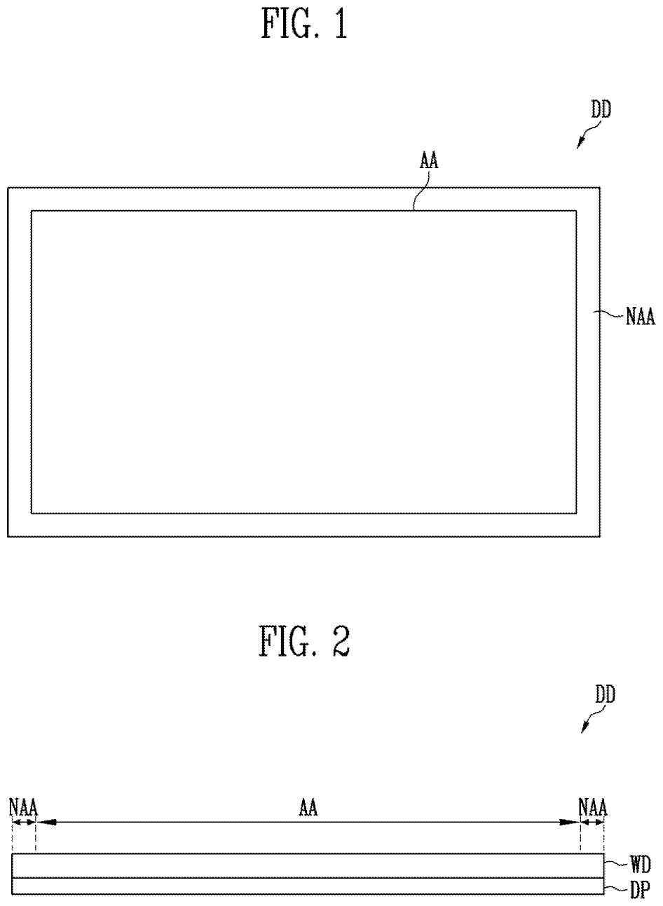

FIGS. 1 to 6 are schematic views illustrating various types of display devices DD.

A display device DD may be a device which is activated according to an electrical signal and displays an image. For example, the display device DD may be used as a display screen of portable electronic devices such as a mobile phone, a smart phone, a tablet personal computer (PC), a mobile communication terminal, an electronic notebook, an electronic book, a portable multimedia player (PMP), a navigation system, and an ultra-mobile PC. The display device DD may be used as a display screen of various products such as a television, a notebook computer, a monitor, an advertisement board, and Internet of things (IOT). Further, the display device DD may be used as a display screen of an automotive display.

The display device DD may have various shapes, such as a rectangular shape, a circular shape, and a polygonal shape, on a plane.

Referring to FIGS. 1 and 2, a display device DD in accordance with an embodiment of the disclosure may include a display area AA and a non-display area NAA surrounding the display area AA. The display area AA may be an area in which an image is displayed. Multiple pixels for displaying the image may be disposed in the display area AA. The non-display area NAA may be an area in which the image is not displayed. Various drivers for driving the plurality of pixels, various lines, and the like may be disposed in the non-display area NAA. The non-display area NAA may be a peripheral edge area except the display area AA, and may be referred to as a bezel area.

The display device DD in accordance with the embodiment of the disclosure may include a window WD and a display panel DP. The window WD may be disposed on a front surface of the display panel DP to protect the display panel DP. An image output from the display panel DP may be recognized by a user while being transmitted through the window WD. The window WD may form an appearance of the display device DD. The window WD may be attached onto the display panel DP by an adhesive layer. For example, the adhesive layer may include an adhesive member, such as an optically clear adhesive or a pressure sensitive adhesive.

The display panel DP may display an image on the front surface thereof. The display panel may be a light emitting display panel. For example, the display panel DP may be an organic light emitting display panel, a quantum dot light emitting display panel, a micro LED display panel, or a nano LED display panel.

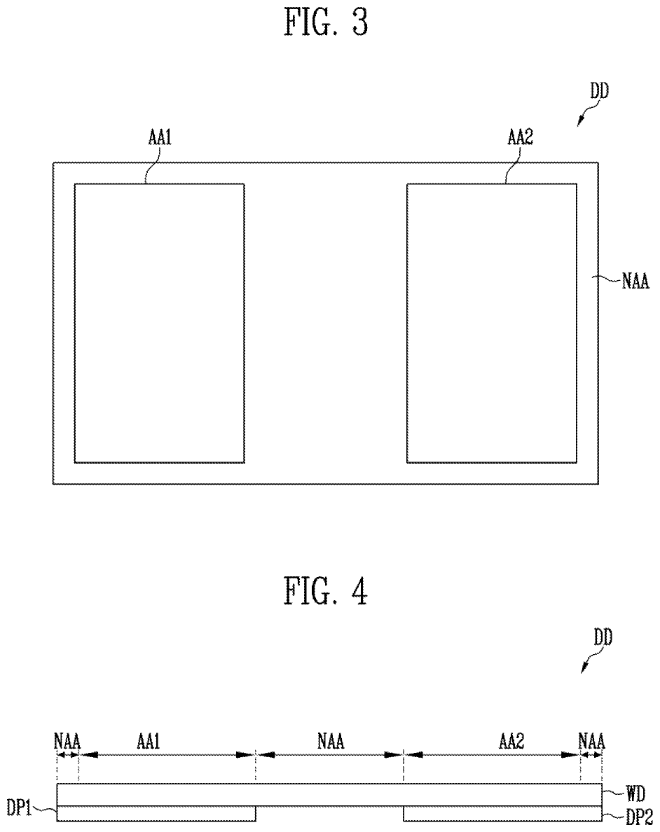

Referring to FIGS. 3 and 4, a display device DD in accordance with an embodiment of the disclosure may include two display areas AA1 and AA2 and a non-display area NAA surrounding the display areas AA1 and AA2. The same image or different images may be displayed in the display areas AA1 and AA2. To this end, the display device DD in accordance with the embodiment of the disclosure may include a window WD and two display panels DP1 and DP2. Each of the display panel DP1 and DP2 may be attached to the window WD through an adhesive layer. The display areas AA1 and AA2 and the display panels DP1 and DP2, which are shown in FIGS. 3 and 4, are merely illustrative, and the sizes and shapes of the display areas AA1 and AA2 and the display panels DP1 and DP2 may be variously modified according to products.

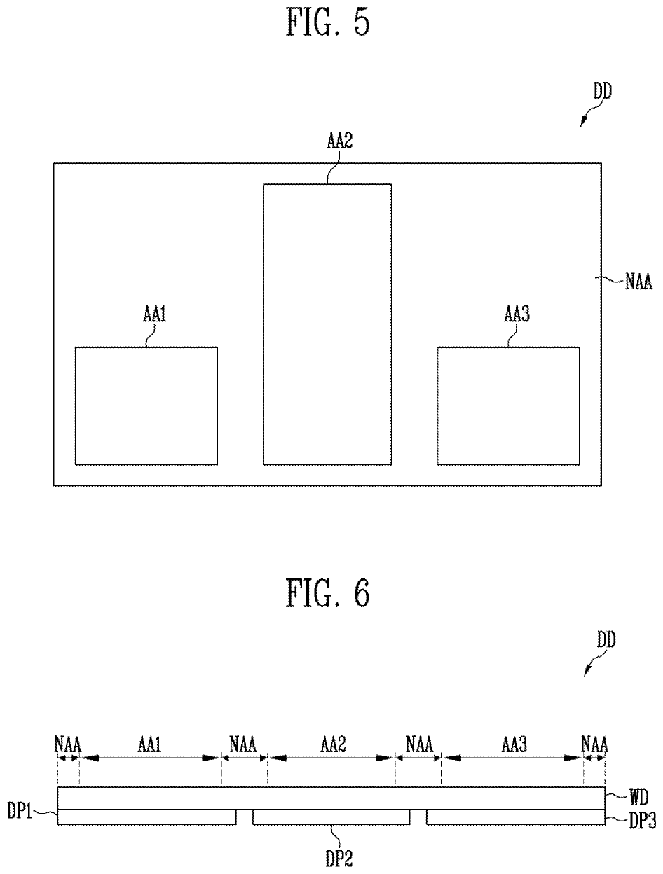

Referring to FIGS. 5 and 6, a display device DD in accordance with an embodiment of the disclosure may include three display areas AA1, AA2, and AA3 and a non-display area NAA surrounding the display areas AA1, AA2, and AA3. The same image or different images may be displayed in the display areas AA1, AA2, and AA3. To this end, the display device DD in accordance with the embodiment of the disclosure may include a window WD and three display panels DP1, DP2, and DP3. Each of the display panels DP1, DP2, and DP3 may be attached to the window WD through an adhesive layer. The display areas AA1, AA2, and AA3 and the display panels DP1, DP2, and DP3, which are shown in FIGS. 5 and 6, are merely illustrative, and the sizes and shapes of the display areas AA1, AA2, and AA3 and the display panels DP1, DP2, and DP3 may be variously modified according to products.

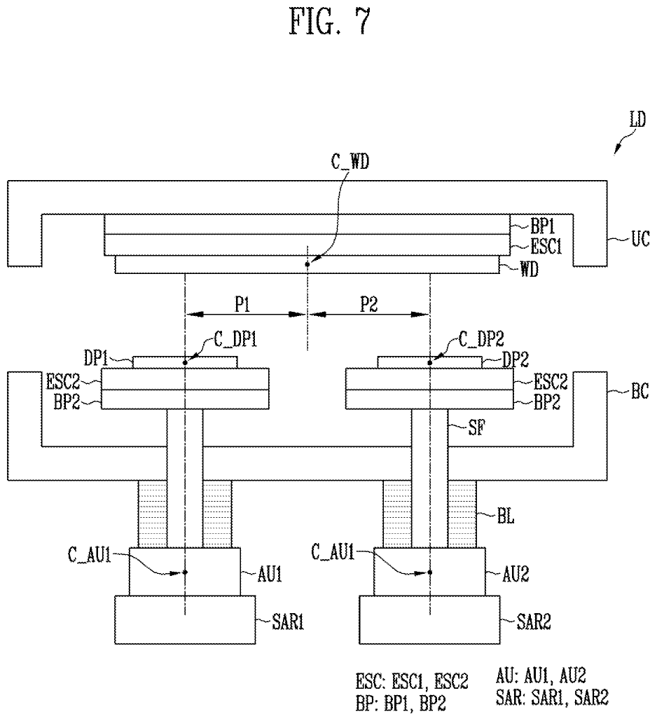

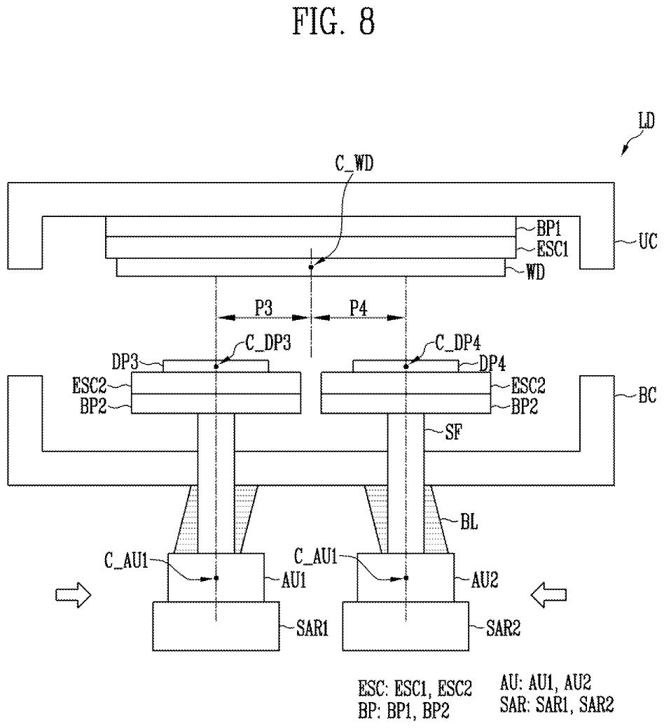

FIGS. 7 and 8 are schematic views illustrating a lamination device LD in accordance with an embodiment of the disclosure. In FIGS. 7 and 8, a lamination device LD for adhering two display panels DP1/DP2 or DP3/DP4 to a window WD is illustrated.

Referring to FIG. 7, the lamination device LD in accordance with the embodiment of the disclosure may include an upper chamber UC, a lower chamber BC, a base plate BP, an electrostatic chuck ESC, at least one shaft SF, at least one bellows BL, an alignment unit (alignment part or aligner) AU, and a single-axis robot SAR. The base plate BP may include a first base plate BP1 and at least one second base plate BP2. The electrostatic chuck ESC may include a first electrostatic chuck ESC1 and at least one second electrostatic chuck ESC2. The alignment unit AU may include a first alignment unit AU1 and a second alignment unit AU2. The single-axis robot SAR may include a first single-axis robot SAR1 and a second single-axis robot SAR2.

The upper chamber UC may be a component which accommodates the window WD. To this end, the first base plate BP1 and the first electrostatic chuck ESC1 may be disposed in the upper chamber UC. The first base plate BP1 may be a component which supports the first electrostatic chuck ESC1 that may be disposed on the first base plate BP1 to fix the window WD. The first electrostatic chuck ESC1 may adsorb (or hold) the window WD, using an electrostatic force, thereby fixing the window WD. The first electrostatic chuck ESC1 may include an electrode layer for providing the electrostatic force and a protective layer for protecting the electrode layer from pressure applied during a lamination process.

A driving means (not shown) for movement of the upper chamber UC may be disposed in the upper chamber UC. For example, the upper chamber UC may perform up/down operations on the lower chamber BC in an upper area of the lower chamber BC. The upper chamber UC may perform a down operation toward the lower chamber BC, of which the position is fixed, to be joined together with the lower chamber BC. As the upper chamber UC and the lower chamber BC may be joined together to form an internal space, a lamination process of the window WD and display panels DP1 and DP2 may be performed. In the lamination process, the internal space of the upper chamber UC and the lower chamber BC, which are joined together, may be maintained in a vacuum state. When the lamination process is completed, the upper chamber UC may perform an up operation to be separated from the lower chamber BC.

The lower chamber BC is a component which accommodates at least one display panel DP (see FIG. 2). In FIG. 7, it is illustrated that the lower chamber BC accommodates two display panels DP1 and DP2. Multiple second base plates BP2 and multiple second electrostatic chucks ECS2 may be disposed in the lower chamber BC. A second base plate BP2 may be a component which supports a corresponding second electrostatic chuck ESC2. The second base plate BP2 may be connected to a corresponding shaft SF. The second electrostatic chucks ESC2 may be disposed on the second base plates BP2 to fix the display panels DP1 and DP2, respectively. The second electrostatic chucks ESC2 may respectively adsorb the display panels DP1 and DP2, using the electrostatic force, to fix the display panels DP1 and DP2. The second electrostatic chuck ESC2 may include an electrode layer for providing the electrostatic force and a protective layer for protecting the electrode layer from pressure applied during the lamination process.

The shaft SF may be a component which moves the second base plate BP2 and the second electrostatic chuck ESC2, corresponding to an alignment operation of the alignment unit AU. To this end, the shaft SF may penetrate the lower chamber BC and may be disposed between the second base plate BP2 and the alignment unit AU. For example, the shaft SF may be disposed between the second base plate BP2 and the first alignment unit AU1. Also, the shaft SF may be disposed between the second base plate BP2 and the second alignment unit AU2.

The bellows BL may be a component which maintains the internal space of the upper chamber UC and the lower chamber BC, which are joined together in the lamination process, to be in the vacuum state. The bellows BL may be disposed between the lower chamber BC and the alignment unit AU to surround a portion of the shaft SF. For example, the bellows BL may surround the shaft SF exposed to the outside between the lower chamber BC and the alignment unit AU.

The alignment unit AU may be a component which aligns the window WD and the display panels DP1 and DP2. For example, the alignment unit AU may be a component which adjusts an adhesion position of the window WD and the display panels DP1 and DP2. The alignment unit AU may include an alignment stage (not shown), and the alignment stage may be moved on an X axis, a Y axis, and a 0 axis, thereby performing an alignment operation of the display panels DP1 and DP2 with respect to the window WD.

The alignment unit AU may individually align the display panels DP1 and DP2. For example, the first alignment unit AU1 may perform an alignment operation of a first display panel DP1 with respect to the window WD. The second alignment unit AU2 may perform an alignment operation of a second display panel DP2 with respect to the window WD.

The single-axis robot SAR may be a component which allows a center of the alignment unit AU and a center of each of the display panels DP1 and DP2 to correspond to each other. In order to more accurately align the window WD and the display panels DP1 and DP2, it is necessary to allow the center of each of the display panels DP1 and DP2 and the center of the alignment unit AU to correspond thereto. The single-axis robot SAR may move the alignment unit AU corresponding to each of centers C_DP1 and C_DP2 of the display panels DP1 and DP2, to allow the center of the alignment unit AU and the center of each of the display panels DP1 and DP2 to correspond to each other. For example, the first single-axis robot SAR1 may move the first alignment unit AU1 such that a center C_DP1 of the first display panel DP1 and a center C_AU1 of the first alignment unit AU1 correspond to each other. The second single-axis robot SAR2 may move the second alignment unit AU2 such that a center C_DP2 of the second display panel DP2 and a center C_AU2 of the second alignment unit AU2 correspond to each other.

The single-axis robot SAR may operate corresponding to a pitch of the display panel DP. The pitch of the display panel DP may refer to a distance between a center C_WD of the window WD and a center of the display panel DP. For example, a pitch P1 of the first display panel DP1 may be a distance between the center C_DP1 of the first display panel DP1 and the center C_WD of the window WD. A pitch P2 of the second display panel DP2 may be a distance between the center C_DP2 of the second display panel DP2 and the center C_WD of the window WD.

The shape or adhesion position of the display panel DP adhered to the window WD may be changed, e.g., according to products. Referring to FIGS. 7 and 8, the display panel DP adhered to the window WD may be changed from the first display panel DP1 and the second display panel DP2 to a third display panel DP3 and a fourth display panel DP4, of which shapes or adhesion positions are different from shapes or adhesion positions of the first display panel DP1 and the second display panel DP2. In case that the shape or adhesion position of the display panel DP is changed, the pitch of the display panel DP may be changed. For example, as an adhesion position of the third display panel DP3 is changed to the right, a pitch P3 of the third display panel DP3 may become smaller than the pitch P1 of the first display panel DP1. Also, as an adhesion position of the fourth display panel DP4 is changed to the left, a pitch P4 of the fourth display panel DP4 may become smaller than the pitch P2 of the second display panel DP2.

In case that the pitch of the display panel DP is changed, the center of the display panel DP and the center of the alignment unit AU do not correspond to each other. Therefore, in order to realign the center of the display panel DP and the center of the alignment unit AU, the alignment unit AU may be moved by operating the single-axis robot SAR. For example, the first alignment unit AU1 may be moved to the right by operating the first single-axis robot SAR1 such that a center C_DP3 of the third display panel DP3 and the center C_AU1 of the first alignment unit AU1 correspond to each other. The second alignment unit AU2 may be moved to the left by operating the second single-axis robot SAR2 such that a center C_DP4 of the fourth display panel DP4 and the center C_AU2 of the second alignment unit AU2 correspond to each other.

In the above-described process, the bellows BL may be horizontally moved together with the alignment unit AU. However, since the position of the lower chamber BC connected to the bellows BL may be fixed, the horizontal movement of the bellows BL may be limited. In case that a change in the pitch of the display panel DP is large, the bellows BL may be damaged during the horizontal movement. In case that the bellows BL is damaged, the internal space of the upper chamber UC and the lower chamber BC, which may be joined together in the lamination process, may be in a non-vacuum state, and therefore, the adhesion property of the window WD and the display panel DP may be deteriorated.

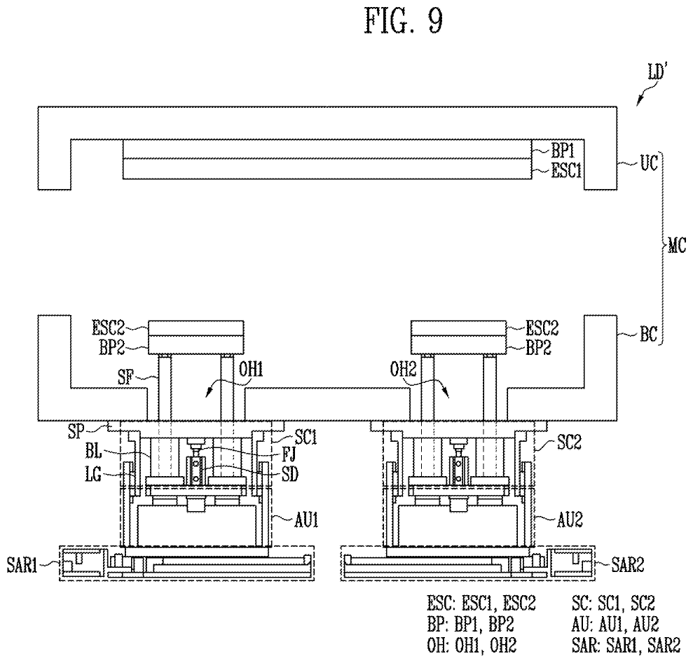

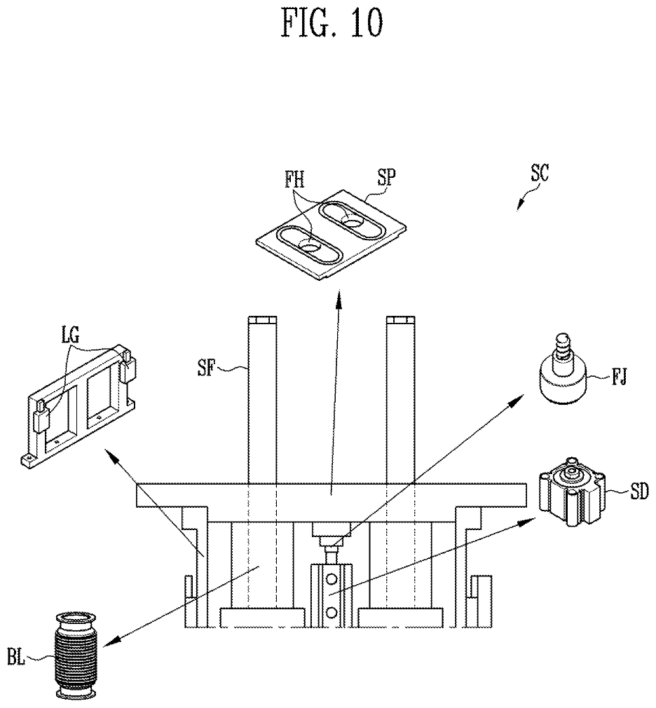

FIG. 9 is a schematic view illustrating a lamination device LD′ in accordance with an embodiment of the disclosure. FIG. 10 is a schematic view illustrating a sub-chamber SC in accordance with an embodiment of the disclosure.

Referring to FIG. 9, the lamination device LD′ in accordance with the embodiment of the disclosure may include an upper chamber, a lower chamber BC, a base plate BP, an electrostatic chuck ESC, at least one shaft SF, at least one bellows BL, at least one sub-chamber SC, an alignment unit AU, and a single-axis robot SAR. Unlike the lamination device LD shown in FIGS. 7 and 8, the lamination device LD′ in accordance with the embodiment of the disclosure may further include the sub-chamber SC. The sub-chamber SC may include a first sub-chamber SC1 and a second sub-chamber SC2. In order to distinguish the upper chamber UC and the lower chamber BC from the sub-chamber SC, the upper chamber UC and the lower chamber BC may be referred to as a main chamber MC. Hereinafter, portions different from those shown in FIGS. 7 and 8 will be mainly described.

At least one shaft may be connected to each second base plate BP2. In FIG. 9, it is illustrated that two shafts SF are connected to each second base plate BP2. However, the disclosure is not limited thereto, and a shaft SF may be connected to each second base plate BP2 as shown in FIGS. 7 and 8.

The lower chamber BC may include at least one opening hole OH formed such that at least one shaft SF penetrates the lower chamber BC. The opening hole OH may be formed by a number of display panels DP (see FIG. 2) adhered to a window WD (see FIG. 7). For example, in case that two display panels DP are adhered to the window WD, the lower chamber BC may include two opening holes OH1 and OH2. The shaft SF is disposed in the opening hole OH, so that a movement space of the shaft SF can be secured.

At least one sub-chamber SC may be provided in the lamination device LD′. The sub-chamber SC may be provided by a number of display panels DP adhered to the window WD. For example, in case that two display panel DP are adhered to the window WD, two sub-chambers SC1 and SC2 may be provided in the lamination device LD′.

Referring to FIGS. 9 and 10, the sub-chamber SC may be disposed between the lower chamber BC and the alignment unit AU. The sub-chamber SC may include a sub-plate SP, a cylinder SD, a linear motion guide (or LM guide) LG, and a floating joint FJ.

The sub-plate SP may include a fixing hole FH for fixing the shaft SF. The sub-plate SP may prevent the shaft SF from moving in a process of allowing a center of the display panel DP and a center of the alignment unit AU to correspond to each other. A number of the fixing holes FH may be equal to a number of fixed shafts SF. In FIGS. 9 and 10, the sub-plate SP in which two fixing holes FH for fixing two shafts SF are formed is illustrated.

The cylinder SD may be a component which allows the sub-chamber SC to move upwards/downwards. The cylinder SD may allow the sub-chamber SC to move upwards or downwards in the process of allowing the center of the display panel DP and the center of the alignment unit AU to correspond to each other.

The LM guide LG may be a component which guides an up/down motion of the sub-chamber SC. The LM guide LG may be disposed at a side of the sub-chamber SC to allow the up/down motion of the sub-chamber SC to be smoothly performed. The LM guide LG may include a guide rail for movement, an LM block slidingly moving on the guide rail, and the like.

The floating joint FJ may be a component which compensates for parallelism between an axial center of the cylinder SD and the up/down motion of the LM guide LG. The floating joint FJ may absorb or prevent eccentricity and declination due to center displacement between the cylinder SD and the LM guide LG, and absorb or prevent deficiency of accuracy of the parallelism between the cylinder SD and the LM guide LG.

A portion of the shaft SF may be disposed in the sub-chamber SC through the sub-plate SP. The bellows BL surrounding a portion of the shaft SF may be disposed in the sub-chamber SC. The bellows BL may surround the shaft SF disposed inside the sub-chamber SC and may be in contact with (or connected to) the sub-plate SP. As described above, since the bellows BL shown in FIGS. 7 and 8 may be connected to the lower chamber BC of which the position is fixed, the horizontal movement of the bellows BL may be limited, and the bellows BL may be damaged in the horizontal movement. On the other hand, since the bellows BL in accordance with an embodiment of the disclosure may be disposed in the sub-chamber SC of which the position is not fixed, the horizontal movement of the bellows BL may not be limited. Accordingly, a force applied to the bellows BW in the horizontal movement may be minimized, and a risk that the bellows BL may be damaged can be eliminated or reduced.

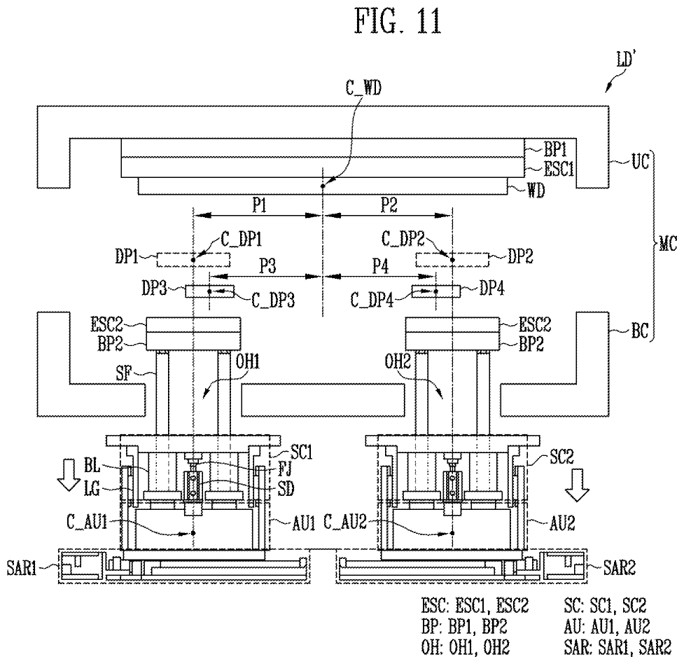

FIGS. 11 to 13 are schematic views illustrating a driving method of the lamination device LD′ in accordance with an embodiment of the disclosure.

Before description, it is assumed that the center of the alignment unit AU of the lamination device LD′ is in a state in which the center of the alignment unit AU corresponds to the center of the display panel DP used in a previous lamination process. For example, the center C_AU1 of the first alignment unit AU1 is in a state in which the center C_AU1 of the first alignment unit AU1 corresponds to the center C_DP1 of the first display panel DP1 used in the previous lamination process, corresponding to the pitch P1 of the first display panel DP1. The center C_AU2 of the second alignment unit AU2 is in a state in which the center C_AU2 of the second alignment unit AU2 corresponds to the center C_DP2 of the second display panel DP2 used in the previous lamination process, corresponding to the pitch P2 of the second display panel DP2.

Hereinafter, a driving method of the lamination device LD′ for allowing the center C_AU1 of the first alignment unit AU1 and the center C_AU2 of the second alignment unit AU2 to respectively correspond to the center C_DP3 of the third display panel DP3 and the center C_DP4 of the fourth display panel DP4, which are to be used in a next lamination process, corresponding to the pitch P3 of the third display panel DP3 and the pitch P4 of the fourth display panel DP4 will be described.

Referring to FIG. 11, a step of lowering at least one sub-chamber SC may be performed. For example, the first sub-chamber SC1 and the second sub-chamber SC2 may be lowered. The sub-chamber SC may move downwards through an operation of the cylinder SD. As the sub-chamber SC is lowered, the sub-chamber SC may be spaced part from the lower chamber BC.

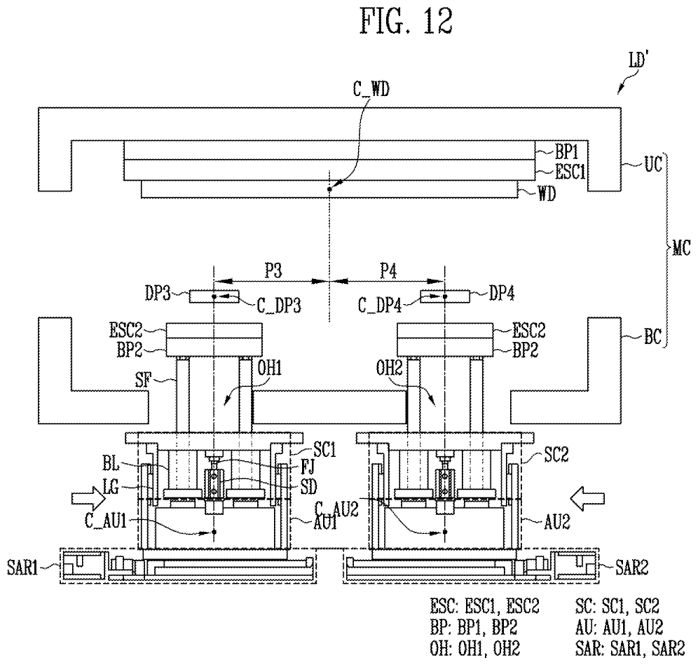

Referring to FIG. 12, a step of allowing the center of at least one alignment unit AU and the center of the display panel DP (see FIG. 2) to correspond to each other by moving the alignment unit AU may be performed. The alignment unit AU may be horizontally moved by the single-axis robot SAR. For example, the first alignment unit AU1 may be moved to the right by the first single-axis robot SAR1, and accordingly, the center C_AU1 of the first alignment unit AU1 and the center C_DP3 of the third display panel DP3 can correspond to each other. The second alignment unit AU2 may be moved to the left by the second single-axis robot SAR2, and accordingly, the center C_AU2 of the second alignment unit AU2 and the center C_DP4 of the fourth display panel DP4 can correspond to each other. The sub-chambers SC1 and SC2 may be horizontally moved together with corresponding alignment units AU1 and AU2, respectively. For example, in a process of allowing the center of the alignment unit and the center of the display panel DP to correspond to each other, the position of the sub-chamber SC may not be fixed and may be moved. Hence, the horizontal movement of the bellows BL disposed in the sub-chamber SC may become smooth, and the horizontal force applied to the bellows BL may be minimized. Thus, deformation or damage of the bellows BL can be prevented.

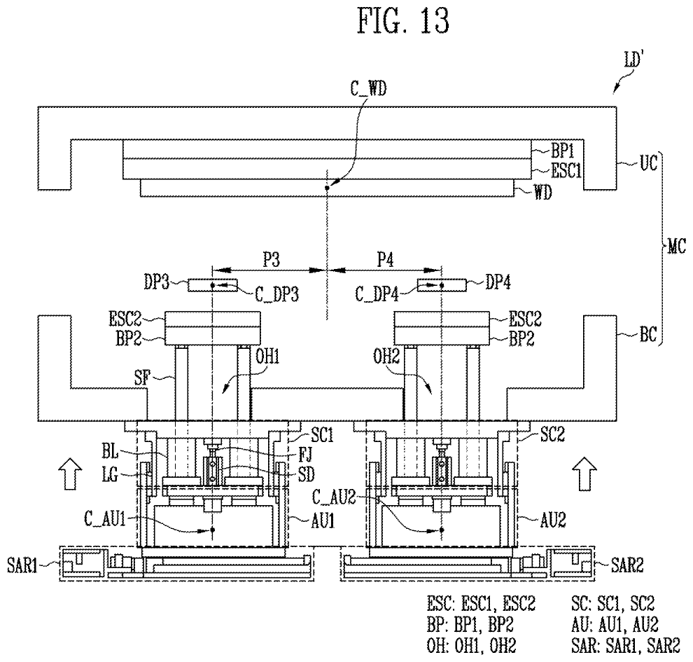

Referring to FIG. 13, a step of raising at least one sub-chamber SC may be performed. For example, the first sub-chamber SC1 and the second sub-chamber SC2 may be raised. The sub-chamber SC may move upwards through an operation of the cylinder SD. As the sub-chamber SC is raised, the sub-chamber SC may be in contact with (or connected to) the lower chamber BC. Accordingly, the upper chamber UC and the lower chamber BC may be joined together, and an internal space to be formed can be maintained in a vacuum state. Thus, the display panels DP3 and DP4, of which shapes or adhesion positions may be changed, can be more accurately adhered to the window WD.

In accordance with the disclosure, the center of an alignment unit of the lamination device can readily correspond to the centers of various types of display panels.

Damage of a bellows may be prevented in a process of allowing the center of the alignment unit and the center of a display panel to correspond to each other, thereby maintaining a vacuum state of the lamination state.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A lamination device comprising:
an upper chamber accommodating a window;
a lower chamber accommodating at least one display panel;
at least one shaft penetrating the lower chamber;
at least one alignment part aligning the at least one display panel and the window; and
at least one sub-chamber disposed between the lower chamber and the at least one alignment part,
wherein at least one bellows surrounding a portion of the at least one shaft is disposed in the at least one sub-chamber.

2. The lamination device of claim 1, wherein
a first base plate and a first electrostatic chuck are disposed in the upper chamber, and
the first electrostatic chuck is disposed on the first base plate and fixes the window.

3. The lamination device of claim 1, wherein
at least one second base plate and at least one second electrostatic chuck are disposed in the lower chamber,
the at least one second base plate is connected to the at least one shaft, and
the at least one second electrostatic chuck is disposed on the at least one second base plate and fixes the at least one display panel.

4. The lamination device of claim 1, wherein
the lower chamber includes at least one opening hole corresponding to the at least one display panel, and
the at least one shaft is disposed in the at least one opening hole.

5. The lamination device of claim 1, wherein the at least one sub-chamber includes:
a sub-plate including a fixing hole fixing the at least one shaft;
a cylinder allowing the at least one sub-chamber to move upwards/downwards;
a linear motion guide (or LM guide) guiding an up/down motion of the at least one sub-chamber; and
a floating joint compensating for parallelism between an axial center of the cylinder and the up/down motion of the LM guide.

6. The lamination device of claim 1, wherein
the upper chamber and the lower chamber are joined together to form an internal space, and
the at least one bellows maintains the internal space to be in a vacuum state.

7. The lamination device of claim 5, wherein the at least one bellows is in contact with the sub-plate.

8. The lamination device of claim 1, further comprising:
at least one single-axis robot disposed on the bottom of the at least one alignment part, the at least one single-axis robot moving the at least one alignment part such that a center of the at least one alignment part and a center of the at least one display panel correspond to each other.

9. The lamination device of claim 8, wherein the at least one sub-chamber moves downwards before the at least one single-axis robot moves the at least one alignment part.

10. The lamination device of claim 8, wherein the at least one sub-chamber moves upwards after the at least one single-axis robot moves the at least one alignment part.

11. The lamination device of claim 1, wherein a number of the at least one display panel is in a range of 1 to 3.

12. A method of driving a lamination device, the method comprising:
lowering at least one sub-chamber disposed between a lower chamber accommodating at least one display panel and at least one alignment part;
allowing a center of the at least one alignment part and a center of the at least one display panel to correspond to each other by moving the at least one alignment part; and
raising the at least one sub-chamber,
wherein at least one bellows surrounding a portion of at least one shaft is disposed in the at least one sub-chamber.

13. The method of claim 12, wherein the at least one sub-chamber includes:
a sub-plate including a fixing hole fixing the at least one shaft;
a cylinder allowing the at least one sub-chamber to move upwards/downwards;
a linear motion guide (or LM guide) guiding an up/down motion of the at least one sub-chamber; and
a floating joint compensating for parallelism between an axial center of the cylinder and the up/down motion of the LM guide.

14. The method of claim 13 wherein the at least one bellows is in contact with the sub-plate.

15. The method of claim 12, further comprising:
joining together an upper chamber accommodating a window and the lower chamber;
maintaining an internal space formed by joining together the upper chamber and the lower chamber to be in a vacuum state; and
adhering the window and the at least one display panel to each other.

16. The method of claim 12, wherein a number of the at least one display panel is in a range of 1 to 3.

17. The method of claim 15, wherein
a first base plate and a first electrostatic chuck are disposed in the upper chamber, and
the first electrostatic chuck is disposed on the first base plate and fixes the window.

18. The method of claim 15, wherein
at least one second base plate and at least one second electrostatic chuck are disposed in the lower chamber,
the at least one second base plate is connected to the at least one shaft, and
the at least one second electrostatic chuck is disposed on the at least one second base plate and fixes the at least one display panel.

19. The method of claim 13, further comprising:
moving the at least one sub-chamber downwards before moving the at least one alignment part by the at least one single-axis robot.

20. The method of claim 13, further comprising:
moving the at least one sub-chamber upwards after moving the at least one alignment part by the at least one single-axis robot.
